(19) United States
(12) Patent Application Publication
(10) Pub. No.: US 2015/0299857 A1
(43) Pub. Date: Oct. 22, 2015

(54) DEPOSITION DEVICE WITH AUXILIARY INJECTORS FOR INJECTING NUCLEOPHILE GAS AND SEPARATION GAS

(71) Applicant: Veeco ALD Inc., Fremont, CA (US)

(72) Inventors: Sang In Lee, Los Altos Hills, CA (US); Jeong Ah Yoon, Hwaseong-Si (KR); Jeong Hee Kim, Seongnam (KR)

(21) Appl. No.: 14/688,768

(22) Filed: Apr. 16, 2015

Related U.S. Application Data
(60) Provisional application No. 61/982,298, filed on Apr. 21, 2014.

(51) Int. Cl. C23C 16/455; C23C 16/50; C23C 16/52; C23C 16/44

(52) U.S. Cl. CPC C23C 16/45544; C23C 16/4412; C23C 16/50; C23C 16/52

(57) ABSTRACT

Embodiments relate to a deposition device for depositing one or more layers of material onto a surface of a substrate using an injector module assembly according to a relative movement between the injector module assembly and the substrate. The injector module assembly injects different gases through auxiliary gas injectors of the injector module assembly onto the surface of the substrate depending on the direction of relative movement between the injector module assembly and the substrate to improve the deposition rate. A first auxiliary gas injector injects nucleophile gas and a second auxiliary gas injector injects separation gas while the injector module assembly and the substrate makes a relative movement in one direction. When the injector module assembly and the substrate makes a relative movement in the opposite direction, the first auxiliary gas injector injects the separation gas and the second auxiliary gas injector injects the nucleophile gas.

### CROSS REFERENCE TO RELATED APPLICATION

This application claims the benefit of priority under 35 U.S.C. §119(e) to U.S. Provisional Application No. 61/982,298 filed on Apr. 21, 2014, which is incorporated by reference herein in its entirety.

### BACKGROUND

1. Field of Art

The present invention relates to depositing one or more layers of materials on a substrate using atomic layer deposition (ALD).

2. Description of the Related Art

An atomic layer deposition (ALD) is a thin film deposition technique for depositing one or more layers of material on a substrate. ALD uses two types of chemical, one is a source precursor and the other is a reactant precursor. Generally, ALD includes four stages: (i) injection of a source precursor, (ii) removal of a physical adsorption layer of the source precursor, (iii) injection of a reactant precursor, and (iv) removal of a physical adsorption layer of the reactant precursor. ALD can be a slow process that can take an extended amount of time or many repetitions before a layer of desired thickness can be obtained.

### SUMMARY

Embodiments relate to depositing a layer by changing materials injected onto a surface of a substrate by an auxiliary injector between a source injector for injecting a source precursor and a reactant injector for injecting a reactant precursor, according to the direction of the relative movement between the injectors and the substrate.

Embodiments relate to depositing a layer by an injector module assembly. A source precursor is injected onto a surface of a substrate by a first source injector of the injector module assembly. A reactant precursor is injected by a reactant injector of the injector module assembly onto the surface of the substrate injected with nucleophile gas. The reactant precursor reacts with the source precursor adsorbed onto the surface of the substrate to deposit a layer of material. The source precursor is injected onto the surface of the substrate by a second source injector of the injector module assembly. A first relative movement is caused between the substrate and the injector module assembly in a first direction parallel to the surface of the substrate. The nucleophile gas to replace or modify ligands of the source precursor adsorbed onto the surface of the substrate is injected onto the surface of the substrate through a first passage between the first source injector and the reactant injector, during the first relative movement. Separation gas is injected onto the surface of the substrate through a second passage between the reactant injector and the second source injector, during the first relative movement. A second relative movement is caused between the substrate and the injector module assembly in a second direction. The separation gas is injected onto the surface of the substrate through the first passage, during the second relative movement. The nucleophile gas is injected onto the surface of the substrate through the second passage, during the second relative movement.

In one or more embodiments, the source precursor, the reactant precursor, the nucleophile gas, and the separation gas are injected simultaneously.

In one or more embodiments, thermal reaction is induced between the source precursor adsorbed onto the surface of the substrate and the nucleophile gas to replace or modify the ligands of the source precursor.

In one or more embodiments, excess source precursor remaining after injecting the source precursor onto the substrate is discharged by the first source injector through a first exhaust. Additionally, excess source precursor remaining after injecting the source precursor onto the substrate by the second source injector is discharged through a second exhaust. In addition, excess reactant precursor remaining after injecting the reactant precursor onto the substrate by the reactant injector is discharged through a third exhaust.

In one or more embodiments, a portion of the reactant precursor is routed through the first passage to the first exhaust during the first relative movement, and a portion of the reactant precursor is routed through the second passage to the second exhaust during the second relative movement.

In one or more embodiments, the nucleophile gas includes at least one of NH₃, H₂O, HCl, SF₂, CH₃NH₂, C₅H₅N, and HCO₂H, and the separation gas includes Ar.

In one or more embodiments, the layer of material includes boron, or one of oxide, nitride, and carbide of metal atoms. The source precursor includes boron or a compound including metal atoms. In case the layer includes oxide materials, the reactant precursor includes plasma or radicals generated by plasma from at least one of N₂O, O₂, H₂O, H₂O₂, CO₂, and O₃. In case the layer includes nitride materials, the reactant precursor includes plasma or radicals generated by plasma from at least one of N₂, NH₃, N₂H₂, mixture of N₂ and Ar, mixture of N₂ and Ne, and mixture of N₂ and H₂. In case the layer includes carbide materials, the reactant precursor includes plasma or radicals generated by plasma from at least one of CH₄, C₂H₆, C₂H₂, and mixture of Ar and CH₄, C₂H₆ or C₂H₂.

In one or more embodiments, an electric signal is applied across electrodes of the reactant injector to generate plasma, the electrodes embedded the reactant injector for generating the reactant precursor.

Embodiments also relate to a deposition device including an injector module assembly. The injector module assembly includes a first source injector, a second source injector, a reactant injector, a first auxiliary gas injector and a second auxiliary gas injector. The first source injector injects source precursor onto a surface of a substrate. The second source injector injects the source precursor onto the surface of the substrate. The reactant injector is formed between the first source injector and the second source injector. The reactant injector injects reactant precursor onto the substrate. The reactant precursor reacts with the source precursor to deposit a layer of material on the substrate. The first auxiliary gas injector is formed between the first source injector and the reactant injector. The first auxiliary gas injector injects onto the substrate below the first auxiliary gas injector nucleophile gas during a first relative movement between the injector module assembly and the substrate, and separation gas onto the substrate during a second relative movement in a direction opposite to the first relative movement. The nucleophile gas replaces or modifies ligands of the source precursor adsorbed onto the substrate. The second auxiliary gas injector is formed between the second source injector and the reactant injector. The second auxiliary gas injector injects onto the substrate below the second auxiliary gas injector the separation gas during the first relative movement and the nucleophile gas during the second relative movement.

In one or more embodiments, the deposition device further includes an actuator coupled to the injector module assembly. The actuator causes the first relative movement or the second relative movement between the injector module assembly and the substrate.

In one or more embodiments, the deposition device further includes a gas assembly to provide the source precursor and the reactant precursor to the first auxiliary gas injector and the second auxiliary gas injector, according to an operation of the actuator.

In one or more embodiments, the deposition device further includes a first exhaust, a second exhaust, and a third exhaust. The first exhaust discharges the source precursor remaining after injecting the source precursor onto the substrate by the first source injector. The first source injector is placed within the first exhaust. The second exhaust discharges the source precursor remaining after injecting the source precursor onto the substrate by the second source injector. The second source injector is placed within the second exhaust. The third exhaust discharges the reactant precursor remaining after injecting the reactant precursor onto the substrate by the reactant injector. The reactant injector is placed within the third exhaust.

In one or more embodiments, the deposition device further includes a pressure controller to control pressure of the first exhaust, the second exhaust, and the third exhaust. During the first relative movement, the pressure controller lowers pressure of the first exhaust compared to the pressure of the third exhaust to route a portion of the reactant precursor to the first exhaust through a first passage below the first auxiliary gas injector. During the second relative movement, the pressure controller lowers pressure of the second exhaust compared to the pressure of the third exhaust to route another portion of the reactant precursor to the second exhaust through a second passage below the second auxiliary gas injector.

### BRIEF DESCRIPTION OF DRAWINGS

FIG. 1 is a cross sectional diagram of a linear deposition device, according to one embodiment.

FIG. 2 is a perspective view of a linear deposition device, according to one embodiment.

FIG. 3 is a perspective view of an injector module assembly of the linear deposition device mounted with source injectors and reactant injectors, according to one embodiment.

FIG. 4 is a bottom view of the injector module assembly of FIG. 3, according to one embodiment.

FIG. 5 is a front view of a body of the injector module assembly before mounting the source injectors and the reactant injectors, according to one embodiment.

FIG. 6 is a perspective view of a reactant injector, according to one embodiment.

FIG. 7 is a perspective view of a source injector, according to one embodiment.

FIG. 8 is a cross sectional view of the injector module assembly, according to one embodiment.

FIG. 9 is a flowchart illustrating a process of depositing a layer using an injector module assembly, according to one embodiment.

### DETAILED DESCRIPTION OF EMBODIMENTS

Embodiments are described herein with reference to the accompanying drawings. Principles disclosed herein may, however, be embodied in many different forms and should not be construed as being limited to the embodiments set forth herein. In the description, details of well-known features and techniques may be omitted to avoid unnecessarily obscuring the features of the embodiments.

In the drawings, like reference numerals in the drawings denote like elements. The shape, size and regions, and the like, of the drawing may be exaggerated for clarity.

Embodiments relate to a deposition device for depositing one or more layers of material onto a surface of a substrate using an injector module assembly according to a relative movement between the injector module assembly and the substrate. The injector module assembly injects different gases through auxiliary gas injectors of the injector module assembly onto the surface of the substrate depending on the direction of relative movement between the injector module assembly and the substrate to improve the deposition rate. A first auxiliary gas injector injects nucleophile gas and a second auxiliary gas injector injects separation gas while the injector module assembly and the substrate makes a relative movement in one direction. When the injector module assembly and the substrate makes a relative movement in the opposite direction, the first auxiliary gas injector injects the separation gas and the second auxiliary gas injector injects the nucleophile gas.

The nucleophile gas described herein refers to (i) a material that transforms a source precursor adsorbed onto the surface of the substrate or (ii) a material that replaces or modifies ligands of the source precursor adsorbed onto the surface of the substrate to enhance reaction between the source precursor and the reactant precursor. In one or more embodiments, the nucleophile gas may enable deposition of material (for example, using atomic layer deposition (ALD)) to be performed at a higher rate, at a lower temperature or both the higher rate and the lower temperature compared to cases when nucleophile gas is not used.

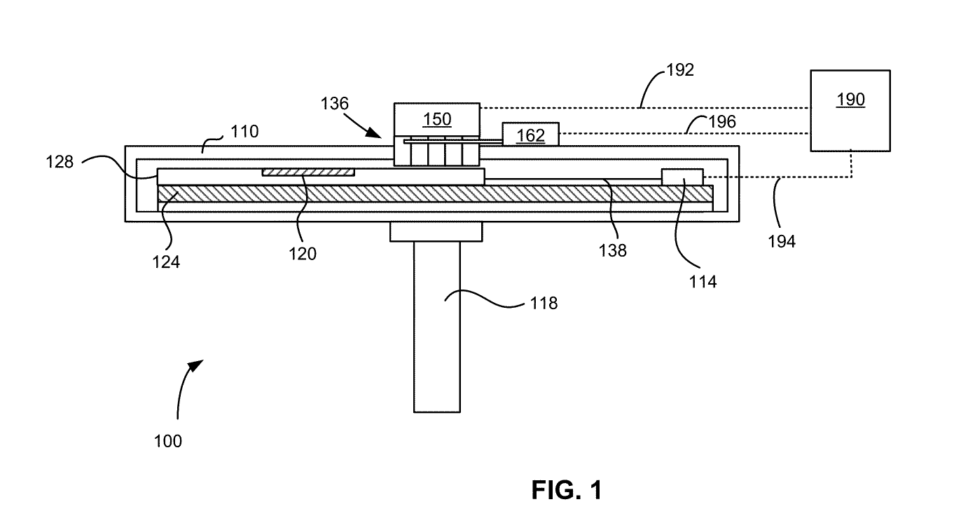

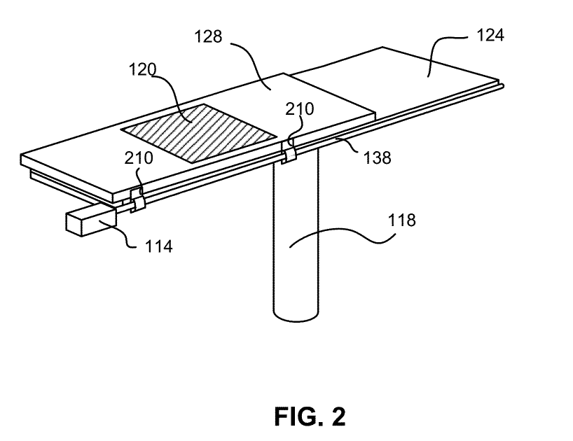

FIG. 1 is a cross sectional diagram of a linear deposition device 100, according to one embodiment. FIG. 2 is a perspective view of the linear deposition device 100 (without chamber walls to facilitate explanation), according to one embodiment. The linear deposition device 100 may include, among other components, a support pillar 118, the process chamber 110, an injector module assembly (IMA) 136, a pressure controller 150, a gas assembly 162, and a controller 190.

The process chamber 110 enclosed by the walls may be maintained in a vacuum state to prevent contaminants from affecting the deposition process. The process chamber 110 contains a susceptor 128 which receives a substrate 120. The susceptor 128 is placed on a support plate 124 for a sliding movement. The support plate 124 may include a temperature controller (e.g., a heater or a cooler) to control the temperature of the substrate 120. The linear deposition device 100 may also include lift pins (not shown) that facilitate loading of the substrate 120 onto the susceptor 128 or dismounting of the substrate 120 from the susceptor 128.

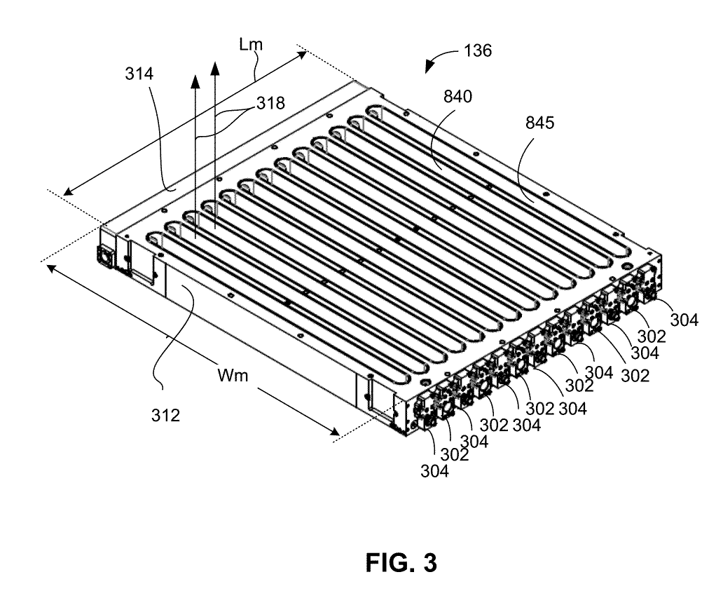

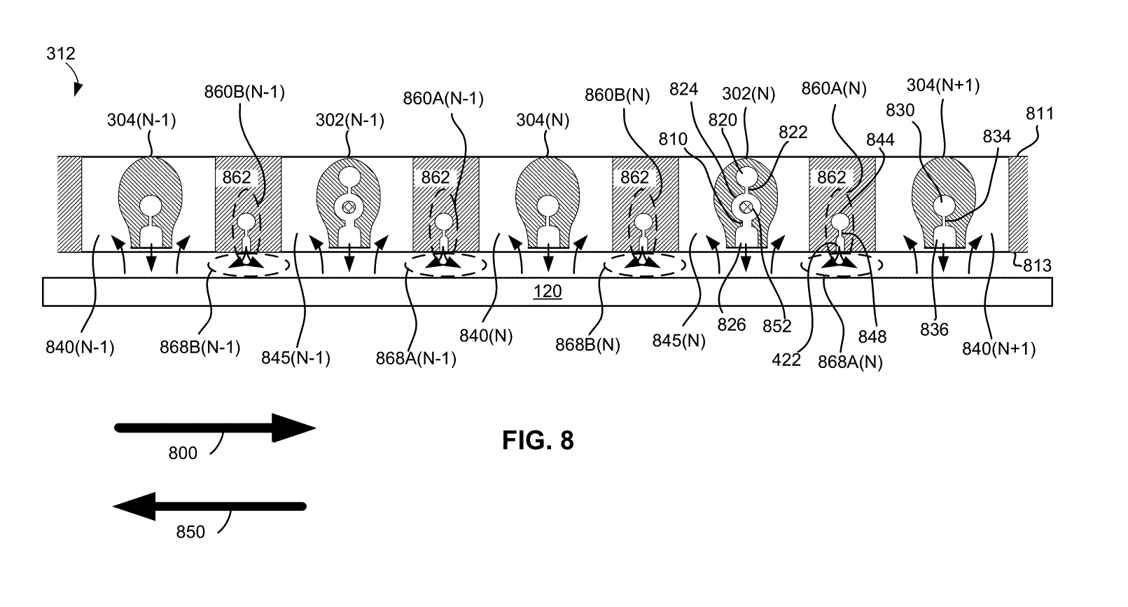

The IMA 136 includes a body and injectors, as described below in detail with reference to FIGS. 3 through 7. The IMA 136 receives source precursor, reactant precursor, separation gas, nucleophile gas from the gas assembly 162. The source precursor and the reactant precursor are routed to different injectors in the IMA 136 for injection onto the substrate. The separation gas and nucleophile gas are routed to different auxiliary gas injectors based on the moving direction of the substrate, as described below in detail with reference to FIG. 8. The body of the IMA 136 is formed with exhausts surrounding the injectors for discharging remaining materials after injecting the source precursor or the reactant precursor onto the substrate 120, as described below in detail with reference to FIG. 8.

The gas assembly 162 is a source of different materials supplied to the IMA 136. The gas assembly 162 supplies the source precursor and pre-reactant precursor to the IMA 136 through pipes (not shown). In addition, the gas assembly 162 supplies the nucleophile gas and the separation gas to the IMA 136 through pipes.

The pressure controller 150 is placed on top of the IMA 136 to control the pressure of exhausts of the IMA 136. The pressure at the exhausts may be controlled, for example, to route materials within the IMA 136 or discharge from the IMA 136. In one embodiment, the pressure controller 150 includes valves for controlling the pressure at the exhausts of the IMA 136 by closing or opening passages from the exhausts. Alternatively or in addition to the valves, the pressure controller 150 may include other actuators such as fans or pumps to control the pressure at each of the exhausts.

The controller 190 controls the overall operation of the deposition device 100. The controller 190 controls, among other components, the pressure controller 150, the gas assembly 162, and the process chamber 110 through control lines 192, 196, and 194. The controller 190 controls, among others, the moving direction and moving speed of the substrate 120 relative to the IMA 136 by sending motor driving signal via the control line 194. The controller 190 controls the gas assembly 162 to route different types of gases through the auxiliary gas injectors by sending signals via the control line 196. Specifically, the controller 190 controls the gas assembly 162 to route the nucleophile gas to one or more auxiliary gas injectors while routing the separation gas to the remaining auxiliary gas injectors when the susceptor 128 is moving in one direction. The controller 190 controls the gas assembly 162 to route the separation gas to the one or more auxiliary gas injectors while routing the nucleophile gas to the remaining auxiliary gas injectors, when the susceptor 128 is moving in a direction opposite to the one direction. Through the control line 192, the controller 190 sends signals to the pressure controller 150 to adjust the pressure level at each exhaust of the IMA 136.

The susceptor 128 is secured to brackets 210 that move across an extended bar 138 with screws formed thereon. The brackets 210 have corresponding screws formed in their holes receiving the extended bar 138. The extended bar 138 is secured to a spindle of an actuator 114 (e.g., a motor). The spindle of the actuator 114 is rotated by the actuator 114 according to the control received from the controller 190 through the control line 194. Hence, the extended bar 138 rotates as the spindle of the actuator 114 rotates. The rotation of the extended bar 138 causes the brackets 210 (and therefore the susceptor 128) to cause a relative movement between the substrate 120 and the IMA 136. By controlling the speed and rotation direction of the actuator 114, the speed and the direction of the relative movement of the substrate 120 and the IMA 136 can be controlled. The use of the actuator 114 and the extended bar 138 is merely an example of a mechanism for causing the relative movement between the IMA 136 and the substrate 120. Various other ways of causing the relative movement between the substrate 120 and the IMA 136 (e.g., use of gears and pinion at the bottom, top or side of the susceptor 128) can be implemented. Moreover, instead of moving the susceptor 128 or the substrate 120, the substrate 120 may remain stationary and the IMA 136 may be moved.

The linear deposition device 100 performs atomic layer deposition (ALD) on the substrate 120 by sequentially injecting the source precursor, separation gas and the reactant precursor. Alternatively or in addition, the deposition device 100 may also deposit one or more layers of material using chemical vapor deposition (CVD) or molecular layer deposition (MLD).

FIG. 3 is a perspective view of the IMA 136 mounted with source injectors 304 and reactant injectors 302, according to one embodiment. The IMA 136 includes a body 312 and an end plate 314 attached to one end of the body 312. The end plate 314 and the body 312 may be secured, for example, by screws.

The body 312 is formed with exhausts 840 and 845 for receiving source injectors 304 and reactant injectors 302. The source injectors 304 and reactant injectors 302 may be mounted into the exhausts 840 and 845 of the body 312 using screws, for example. The source injectors 304 and reactant injectors 302 can be removed from the body 312 for replacement or cleaning

The IMA 136 has a width of Wm and a length of Lm. Each of the exhausts 840 and 845 extends along the width Wm of the IMA 136. Each of the exhausts 840 and 845 extends from the bottom surface of the body 312 to the top surface of the body 312. When mounted, the source injector 304 injects source precursor and the reactant injector 302 injects reactant precursor through respective injection port at the bottom. A source exhaust 840 discharges excess source precursor and a reactant exhaust 845 discharges excess reactant precursor through the top as shown by arrows 318.

As shown, the source injectors 304 and reactant injectors 302 are mounted onto the body 312. In the example of FIG. 3, the source injectors 304 and reactant injectors 302 are arranged in an alternating manner. However, the source injectors 304 and reactant injectors 302 may be arranged in a different manner. Moreover, only the source injectors 304 or reactant injectors 302 may be mounted onto the body 312. By passing the substrate 120 below the IMA 136, either with a rotational motion or linear motion, an area of the substrate 120 is sequentially exposed to source precursors and reactant precursors to deposit a layer.

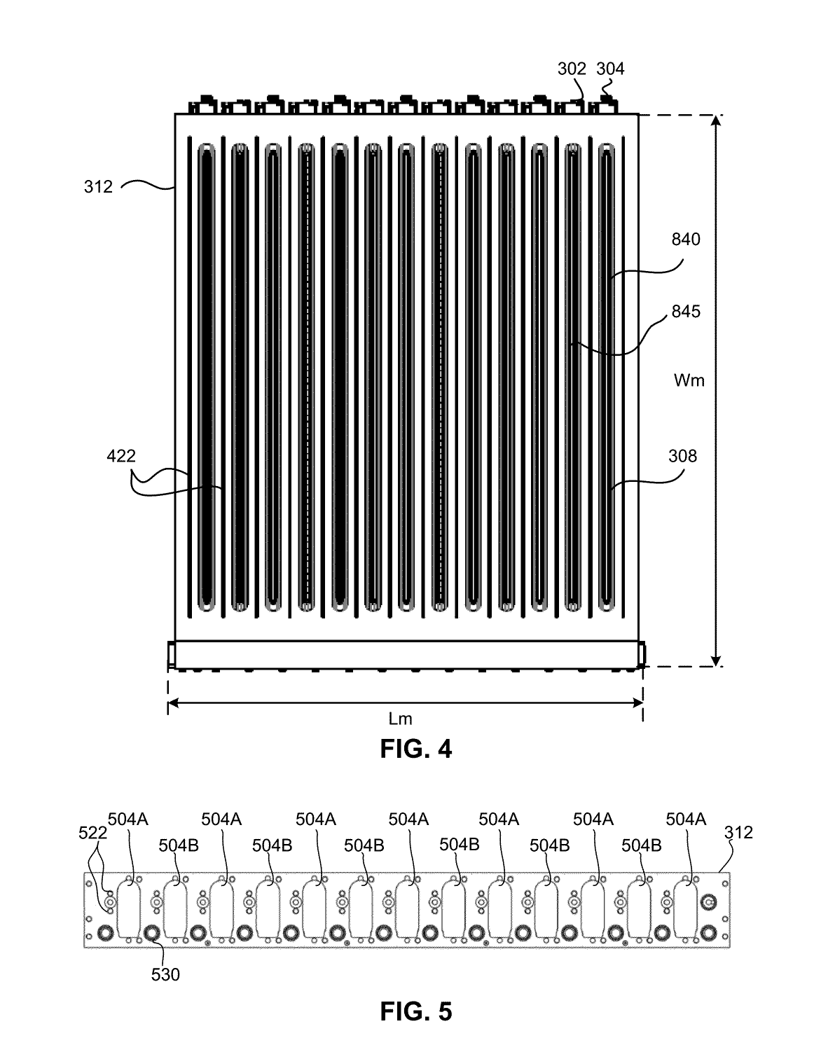

FIG. 4 is a bottom view of the injector module assembly of FIG. 3, according to one embodiment. The source injectors 304 are exposed through source exhaust 840 to inject source precursor onto the substrate 120. The reactant injectors 302 are exposed through reactant exhaust 845 to inject reactant precursor onto the substrate 120. By shifting the IMA 136 or the substrate 120, the source precursor and the reactant precursor can be sequentially injected onto an area of the substrate 120 to deposit a layer.

The body 312 includes auxiliary gas injectors with slits 422 to inject, for example, nucleophile gas or separation gas onto the substrate 120. The slits 422 are formed at the leading end of the body 312, the trailing end of the body 312, and between the source exhausts 840 and the reactant exhausts 845. The slits 422 at the leading end and the trailing end of the body 312 inject gas that functions to prevent the source precursor or the reactant precursor that are not discharged via exhausts from leaking out into the interior of the process chamber 110 other than an area between the IMA 136 and the susceptor 128. The gas injected for this purpose may be the same gas used as the separation gas.

FIG. 5 is a front view of the injector module assembly 136 before mounting the source injectors 304 and reactant injectors 302, according to one embodiment. In one embodiment, the source injectors 304 are inserted through entrances 504A, and the reactant injectors 302 are inserted through entrances 504B. Around the entrances 504A and 504B, screw holes are formed so that source injectors 304 and reactant injectors 302 can be secured by screws. Between the entrances 504, auxiliary gas injectors (not shown) are formed, where each auxiliary gas injector receives separation gas or nucleophile gas through input ports 530.

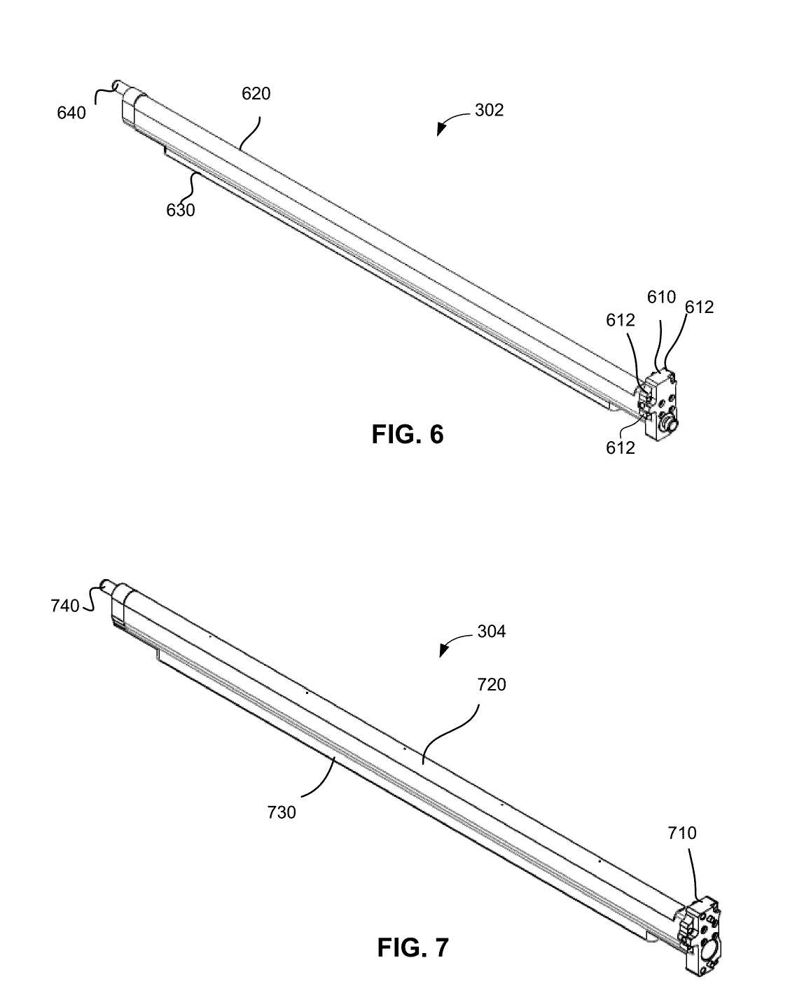

FIG. 6 is a perspective view of the reactant injector 302, according to one embodiment. In one embodiment, the reactant injector 302 receives the reactant precursor from the gas assembly 162. In another embodiment, the reactant injector 302 generates reactant precursors (e.g., radicals) by generating plasma in a chamber formed in the reactant injector 302 that receives gas or mixture from the gas assembly 162. The reactant injector 302 may include, among other parts, an elongated body 620, a protruding leg 640 at one end of the elongated body 620, and an end block 610 at the other end of the elongated body 620. The elongated body 620 includes injection port 630 and is formed with a gas channel 820, reaction chamber 826, and radical chamber 824, as described below in detail with reference to FIG. 8. During operation, the injection port 630 injects the reactant precursor onto the substrate.

The protruding leg 640 extends along the length of the reactant injector 302. When assembling, the protruding leg 640 is inserted into the entrance 504B. The protruding leg 640 is, for example, cylindrical in shape.

The end block 610 is used for securing the reactant injector 302 to the body 312. For this purpose, the end block 610 includes screw holes 612 for receiving screws. A power line is also connected to the end block 610 to provide electric signal for generating plasma within the elongated body 620. Also, gas or mixture for generating the radicals is injected into the reactant injector 302 via the end block 610.

FIG. 7 is a perspective view of a source injector 304, according to one embodiment. The source injector 304 is different from the reactant injector 302 in that the source injector 304 does not generate radicals but merely injects gas or mixture through the injection port 730 onto the substrate 120. Similar to the reactant injector 302, the source injector 304 includes a protruding leg 740, an elongated body 720, and an end block 710. The elongated body 720 includes an injection port 730. The elongated body 720 is formed with gas channel 830 and reaction chamber 836, as described below in detail with reference to FIG. 8.

The structure and the function of the protruding leg 740 and the end block 710 are substantially the same as the protruding leg 640 and the end block 610 except that the end block 710 is not connected to a power line, and therefore, the detailed description of the protruding leg 740 and the end block 710 is omitted herein for the sake of brevity.

Although embodiments are described with reference to FIGS. 1 through 7 using a linear deposition device, the same principle can be applied to rotational deposition device where substrates are placed on a susceptor that rotates about an axis. The injectors of the rotational deposition device may be placed at different circumferential locations so that the substrate passes below the injectors as the susceptor is rotated about the axis. Other than moving the susceptor (and the substrate) in a rotating manner instead of a linear manner, the same principle of changing gas injected into the auxiliary injectors can be used in the rotational deposition device.

FIG. 8 is a cross sectional view of the IMA 136 mounted with the source injectors 304 and the reactant injectors 302, according to one embodiment. In one embodiment, the source exhausts 840 and the reactant exhausts 845 are interposed with each other. The source injectors 304 and the reactant injectors 302 are inserted into the source exhausts 840 and the reactant exhausts 845, respectfully. Between the source exhausts 840 and the reactant exhausts 845, walls 862 extending from the bottom surface 813 to the top surface 811 are formed. Each wall 862 includes an auxiliary gas injector 860 for injecting separation gas or nucleophile gas.

The reactant injector 302 is formed with a gas channel 820 that extends along the length of the elongated body 620. Gas for generating the reactant precursor is injected into a radical chamber 824 from the gas channel 820 via gas holes 822. The radical chamber 824 may be coaxial capacitively coupled plasma (CCP) reactor. Within the radical chamber 824, radicals are produced from the pre-reactant precursor by generating plasma between an electrode 852 and the interior surface of the radical chamber 824. The generated radicals (i.e., reactant precursors) are transferred via a slit 810, for example having a width of 1 mm to 5 mm, to a reaction chamber 826 where the reactant precursors are injected onto the substrate 120 on the susceptor 128.

The source injector 304 is formed with a gas channel 830 that extends along the length of the elongated body 620. The source precursor is injected into a reaction chamber 836 formed in the elongated body 620 from the gas channel 830 via gas holes 834.

The auxiliary gas injector 860 is formed within the walls 862 of the body 312. The auxiliary gas injector 860 includes a gas channel 844 and a slit 422. The nucleophile gas or the separation gas is provided to the slit 422 via the gas channel 844 and the gas holes 848 between the slit 422 and the gas channel 844. The separation gas is injected into a passage 868 at the bottom of the wall 862 between the source exhaust 840 and the reactant exhaust 845.

The excess reactant precursors (or gas reverted to inert state) and part of the gas injected by the auxiliary gas injectors are discharged via the reactant exhausts 845 formed between the walls 862 surrounding the reactant injectors 302. Similarly, excess source precursors and part of the gas injected by the auxiliary gas injectors are discharged via the source exhausts 840 formed between the walls 862 surrounding the source injectors 304.

In one embodiment, a portion of the reactant precursors injected from a reactant injector 302(N−1) in a reactant exhaust 845(N−1) is routed through the passage 868B(N−1) injected with nucleophile gas to an adjacent source exhaust 840(N−1) before the reactant injector 302(N−1) in the moving direction of the substrate 120. However, the reactant precursors are not routed to another adjacent source exhaust 840(N) after the reactant injector 302(N−1) in the moving direction of the substrate 120 because the passage 868A(N−1) between the reactant exhaust 845(N−1) and the other adjacent source exhaust 840(N) is filled with the separation gas.

In one embodiment, to prevent the reactant precursors from flowing to the adjacent source exhaust 840, the pressure level of the reactant exhaust 845 is kept lower than the pressure level of the source exhaust 840 by the pressure controller 150. Therefore, the nucleophile gas injected into the passage 868 and the reactant precursors are routed to the adjacent source exhaust 840 and discharged out of the IMA 136. By transferring the nucleophile gas and the reactant precursors to the adjacent source exhaust 840 through the passage 868 injected with the nucleophile gas, the source precursors adsorbed on a surface of the substrate 120 can be further exposed to the nucleophile gas and the reactant gas. Hence, the deposition rate can be improved.

While the substrate 120 is moving in a direction indicated by arrow 800, the auxiliary gas injector 860B injects nucleophile gas, and the auxiliary gas injector 860A injects separation gas. Because the source injector 304, the auxiliary gas injector 860B, the reactant injector 302 and the auxiliary gas injector 860A are arranged along the direction of arrow 800, a region of a surface of the substrate 120 is sequentially exposed to the source precursor, the nucleophile gas, the reactant precursor, and the separation gas as the substrate 120 moves in the direction of arrow 800 to form one or more layers. Therefore, the nucleophile gas is injected onto the region of the surface of the substrate 120 adsorbed with the source precursor, but before being exposed to the reactant precursor. The nucleophile gas replaces ligands of the source precursor to enhance reaction between the source precursor and the reactant precursor.

After the region of the surface of the substrate 120 is injected with source precursor and reactant precursor, a layer of material is deposited on the region of the surface of the substrate 120. The separation gas is then injected into a passage 868 under the auxiliary gas injector 860A to prevent the source precursor injected by the next source injector 304 from coming into contact with the reactant precursor routed through the passage 868. In this way, the formation of particles in the passage 868 due to the reaction of the source precursor and the reactant precursor can be prevented. Additionally, reaction between the source precursor and the reactant precursor before the source precursor is adsorbed on the substrate 120 can be prevented.

Then the same region of surface of the substrate 120 passes below another set of the source injector 304, the auxiliary gas injector 860B, the reactant injector 302 and the auxiliary gas injector 860A to deposit another layer of material on the region of the surface of the substrate 120. As region of the surface of the substrate moves in the direction indicated by arrow 800. The process of depositing a layer of material may be repeated as the region of the surface of the substrate passes below the set of injectors until the region of the substrate reaches slit 422 at the leading end of the body 312 and moves away from the IMA 136.

After the substrate 120 reaches the rightmost end of its movement in the direction as indicated by arrow 800, the substrate 120 starts moving in the other direction indicated by arrow 850. The same region of the surface of the substrate passes the slit 422 at the leading end of the body 312, and then moves below the sets of injectors in a sequence reverse to the case where the substrate was moving in the direction indicated by arrow 800. However, materials being injected by the auxiliary gas injectors 860B and the auxiliary gas injectors 860A are interchanged during the movement in the direction indicated by arrow 850. The reason for interchanging the gas injected into the auxiliary gas injectors 860A and 860B is to accommodate the change of sequence in which the source and reactant precursors are injected when the substrate is moving in the opposite direction.

In one embodiment, the IMA 136 includes pairs of a source injector 304 and a reactant injector 302, and an additional source injector 304. The source injectors 304 and reactant injectors 302 are interposed with each other, where a first source injector 304(1) is located near the leading end of the IMA 136 and a last source injector 304(N+1) is located near the trailing end of the IMA 136. The IMA 136 also includes an even number of auxiliary gas injectors 860, where each auxiliary gas injector 860 is located between a source injector and a reactant injector. A first group of auxiliary gas injectors appearing after the source injectors inject nucleophile gas and a second group of auxiliary gas injectors appearing after the reactant injectors inject separation gas into the passage 868 according to the direction of the relative movement. In this configuration, the surface of the substrate 120 is exposed to the source precursor first then subsequently exposed to the nucleophiles gas and the reactant precursor, when the substrate moves in the direction indicated by the arrow 800 or 850.

Assuming that the injectors are arranged in the sequence of [S1-B1-R1]-A1-[S2-B2-R2] . . . [S(N−1)-B(N−1)-R(N−1)]-A(N−1)-[SN-BN-RN]-A(N)-S(N+1) (where “S” represents the source injector 304, “B” represents the auxiliary gas injector 860B, “R” represents the reactant injector 302, “A” represents the auxiliary gas injector 860A, “N” represents the total number of injector sets in the direction indicated by arrow 800 and each bracket indicates that a layer of material is deposited), a layer is deposited on the whenever the substrate passes through a combination of S-B-R. Therefore, the auxiliary gas injectors 860B inject the nucleophile gas onto the substrate to enhance the deposition of the layer after injecting the source precursor, whereas the auxiliary gas injectors 860A inject separation gas to prevent the reactant precursor injected in a current set of injectors (e.g., R1) from coming into contact with the source precursor in the next set of injectors (e.g., S2). The source injector S(N+1) does not contribute to the formation of layers, when the substrate 120 moves in the direction indicated by the arrow 800. The source precursor injected by the source injector S(N+1) may react with reactant precursor injected by the reactant injector R(N), after the substrate 120 completes moving in the direction indicated by the arrow 800 and moves in the other direction indicated by the arrow 850.

When the direction of the movement of the substrate is reversed and moves in the direction indicated by arrow 850, the substrate moves below the injectors in the sequence of [S+1-AN-RN]-BN-[SN-A(N−1)-R(N−1)]-B(N−1) . . . [S2-A1-R1]-B1-S1. The auxiliary gas injectors 860A now appear between the source injectors 304 and the reactant injectors 302 for depositing a layer of material. Therefore, the auxiliary gas injectors 860A inject the nucleophile gas whereas the auxiliary gas injectors 860B inject the separation gas, when the substrate moves in the direction indicated by arrow 850. The source injector S1 does not contribute to the formation of layers, when the substrate 120 moves in the direction indicated by the arrow 850. The source precursor injected by the source injector S(1) may react with reactant precursor injected by the reactant injector R(1), after the substrate 120 completes moving in the direction indicated by the arrow 850 and moves in the other direction indicated by the arrow 800.

### Example Operation of the IMA

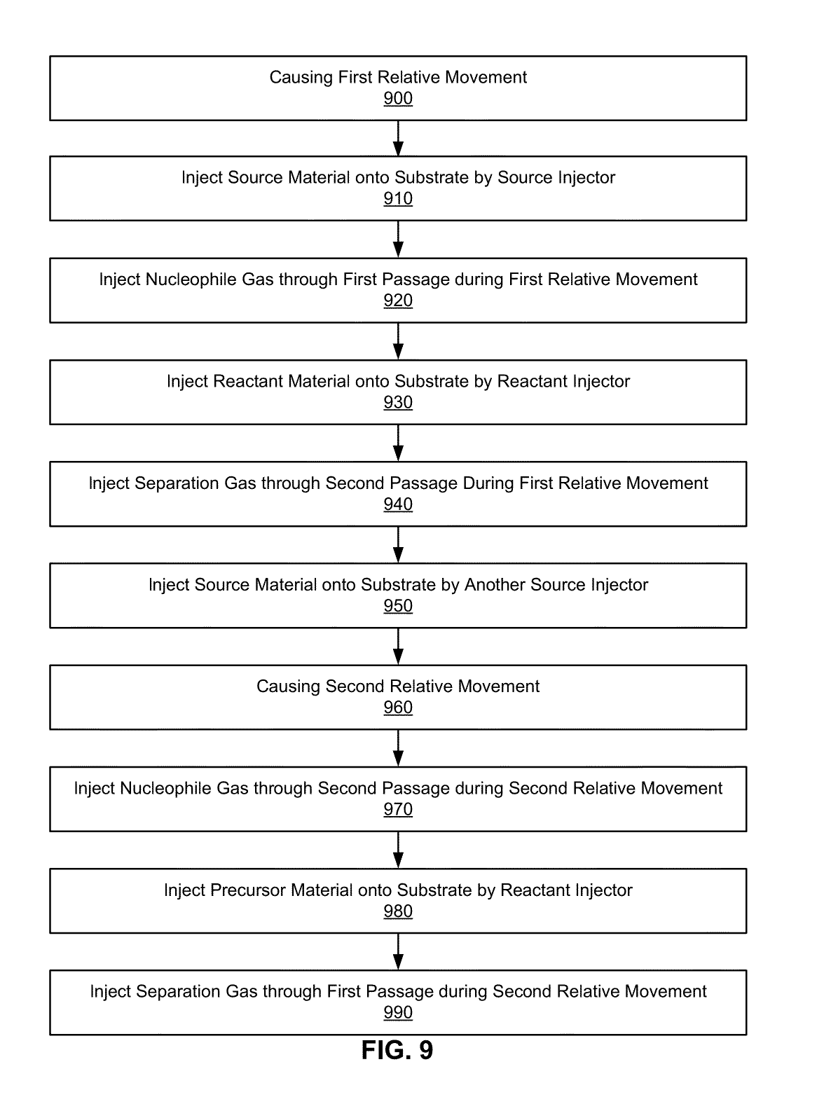

FIG. 9 is a flowchart illustrating a process of depositing a layer using the IMA 136 of FIG. 8, according to one embodiment. The substrate or the IMA is moved to cause 900 a first relative movement between the substrate and the IMA. Source precursor is injected 910 onto a substrate by a source injector during the first relative movement. The source precursor remaining after injecting the source precursor onto the substrate may be discharged through a source exhaust.

A portion of the substrate exposed to the source precursor may then be moved below a first auxiliary gas injector during the first relative movement. Below the first auxiliary gas injector, the portion of the substrate is injected 920 with the nucleophile gas through a first passage during the first relative movement. Thermal reaction may be induced between the source precursor adsorbed onto the surface of the substrate and the nucleophile gas to replace the ligands of the source precursor.

The portion of the substrate exposed to the source precursor and the nucleophile gas may then be moved below a reactant injector during the first relative movement. Below the reactant injector, the portion of the substrate is injected 930 with the reactant precursor to form a layer. The reactant precursor remaining after injecting the reactant precursor onto the substrate may be discharged through a reactant exhaust.

The portion of the substrate exposed to the reactant precursor may be then moved below a second auxiliary gas injector during the first relative movement. Below the second auxiliary gas injector, the portion of the substrate is injected 940 with the separation gas through a second passage during the first relative movement.

The portion of the substrate exposed to the separation gas may be then moved below another source injector during the first relative movement. Below the other source injector, the portion of the substrate is injected 950 with the additional source precursor. The source precursor remaining after injecting the additional source precursor onto the substrate by the other source injector may be discharged through another source exhaust.

During or after the source precursor is injected by the other source injector, a second relative movement opposite to the first relative movement is caused 960 between the substrate and the IMA.

The portion of the substrate exposed to the source precursor by the other source injector may be then moved below the second auxiliary gas injector during the second relative movement. Below the second auxiliary gas injector, the portion of the substrate is injected 970 with the nucleophile gas through the second passage during the second relative movement. Thermal reaction may be induced between the source precursor adsorbed onto the surface and the nucleophile gas to replace the ligands of the source precursor.

The portion of the substrate exposed to the source precursor by the other source injector and the nucleophile gas by the second auxiliary gas injector may be then moved below the reactant injector during the second relative movement. Below the reactant injector, the portion of the substrate is injected 980 with the reactant precursor to form another layer. The reactant precursor remaining after injecting the reactant precursor onto the substrate may be discharged through the reactant exhaust.

The portion of the substrate exposed to the reactant precursor may be then moved below the first auxiliary gas injector during the second relative movement. Below the first auxiliary gas injector, the portion of the substrate is injected 940 with the separation gas through the first passage during the second relative movement.

After completing the second movement, the process in FIG. 9 may be repeated to deposit additional layers on the substrate.

Advantageously, by interchanging the materials injected through the auxiliary gas injectors 860 according to the relative movement between the substrate 120 and the IMA 136, the IMA 136 can deposit one or more layers during both movements instead of a single movement in one direction.

### Example Materials

In one implementation, the layer of material deposited includes boron (B), or one of oxide, nitride, and carbide of metal atoms. To deposit the layer, the source precursors including boron or compound including metal atoms (e.g., Tetrakis(dimethylamino)titanium (TDMAT)) are injected onto a surface of the substrate 120. To deposit the layer including oxide of metal atoms, the reactant precursors including plasma or radicals generated by plasma from at least one of N₂O, O₂, H₂O, H₂O₂, CO₂, and O₃ can be used. To deposit the layer including nitride of metal atoms, the reactant precursor including plasma or radicals generated by plasma from at least one of N₂, NH₃, N₂H₂, mixture of N₂ and Ar, mixture of N₂ and Ne, and mixture of N₂ and H₂, and N₂H₂ can be used. To deposit the layer including carbide of metal atoms, the reactant precursor including plasma or radicals generated by plasma from at least one of CH₄, C₂H₆, C₂H₂, and mixture of Ar and CH₄, C₂H₆ or C₂H₂ can be used.

For the nucleophile gas, materials including at least one of NH₃, H₂O, HCl, SF₂, CH₃NH₂, C₅H₅N, and HCO₂H may be used.

For the separation gas, inert gas such as Argon (Ar) may be used.

While particular embodiments and applications have been illustrated and described, the disclosed embodiments are not limited to the precise construction and components disclosed herein. Various modifications, changes and variations, may be made in the arrangement, operation and details of the method and apparatus disclosed herein.

What is claimed is:

1. A method of depositing a layer by an injector module assembly, the method comprising:
injecting, by a first source injector, source precursor onto a surface of a substrate;
injecting, by a reactant injector, reactant precursor onto the surface of the substrate injected with nucleophile gas, the reactant precursor reacting with the source precursor adsorbed onto the surface of the substrate to deposit a layer of material;
injecting, by a second source injector, the source precursor onto the surface of the substrate;
causing a first relative movement between the substrate and the injector module assembly in a first direction parallel to the surface of the substrate;
injecting, through a first passage between the first source injector and the reactant injector, the nucleophile gas onto the surface of the substrate during the first relative movement;
injecting, through a second passage between the reactant injector and the second source injector, separation gas onto the surface of the substrate during the first relative movement;
causing a second relative movement between the substrate and the injector module assembly in a second direction;
injecting, through the first passage, the separation gas onto the surface of the substrate during the second relative movement; and
injecting, through the second passage, the nucleophile gas onto the surface of the substrate during the second relative movement.

2. The method of claim 1, wherein the source precursor, the reactant precursor, the nucleophile gas and the separation gas are injected simultaneously.

3. The method of claim 1, further comprising inducing thermal reaction between the source precursor adsorbed onto the surface of the substrate and the nucleophile gas to replace or modify ligands of the source precursor.

4. The method of claim 1, further comprising:
discharging excess source precursor remaining after injecting the source precursor onto the substrate by the first source injector through a first exhaust;
discharging excess source precursor remaining after injecting the source precursor onto the substrate by the second source injector through a second exhaust; and
discharging excess reactant precursor remaining after injecting the reactant precursor onto the substrate by the reactant injector through a third exhaust.

5. The method of claim 4, further comprising:
during the first relative movement, routing a portion of the reactant precursor through the first passage to the first exhaust; and
during the second relative movement, routing another portion of the reactant precursor through the second passage to the second exhaust.

6. The method of claim 5, further comprising:
during the first relative movement, lowering pressure of the first exhaust compared to pressure of the third exhaust to route the portion of the reactant precursor through the first passage to the first exhaust; and
during the second relative movement, lowering pressure of the second exhaust compared to the pressure of the third exhaust to route the other portion of the reactant precursor through the second passage to the second exhaust.

7. The method of claim 1, wherein the nucleophile gas includes at least one of NH₃, H₂O, HCl, SF₂, CH₃NH₂, C₅H₅N, and HCO₂H, and the separation gas includes Ar.

8. The method of claim 1, wherein the layer of material includes boron, or one of oxide, nitride, and carbide of metal atoms.

9. The method of claim 1, wherein the source precursor includes boron or compound including metal atoms.

10. The method of claim 1, wherein the layer includes oxide materials, and the reactant precursor includes plasma or radicals generated by plasma from at least one of N₂O, O₂, H₂O, H₂O₂, CO₂, and O₃.

11. The method of claim 1, wherein the layer includes nitride materials, and the reactant precursor includes plasma or radicals generated by plasma from at least one of N₂, NH₃, N₂H₂, mixture of N₂ and Ar, mixture of N₂ and Ne, and mixture of N₂ and H₂.

12. The method of claim 1, wherein the layer includes carbide materials, and the reactant precursor includes plasma or radicals generated by plasma from at least one of CH₄, C₂H₆, C₂H₂, and mixture of Ar and CH₄, C₂H₆ or C₂H₂.

13. The method of claim 1, further comprising applying an electric signal across electrodes of the reactant injector, the electrodes embedded in the reactant injector to generate plasma for generating the reactant precursor.

14. A deposition device comprising:
an injector module assembly comprising:
a first source injector configured to inject source precursor onto a surface of a substrate,
a second source injector configured to inject the source precursor onto the surface of the substrate,
a reactant injector between the first source injector and the second source injector, the reactant injector configured to inject reactant precursor onto the substrate, the reactant precursor reacting with the source precursor to deposit a layer of material on the substrate,
a first auxiliary gas injector between the first source injector and the reactant injector, the first auxiliary gas injector configured to inject, onto the substrate below the first auxiliary gas injector, nucleophile gas during a first relative movement between the injector module assembly and the substrate, and separation gas onto the substrate during a second relative movement opposite to the first relative movement, the nucleophile gas replacing or modifying ligands of the source precursor adsorbed onto the substrate, and
a second auxiliary gas injector between the second source injector and the reactant injector, the second auxiliary gas injector configured to inject, onto the substrate below the second auxiliary gas injector, the separation gas during the first relative movement and the nucleophile gas during the second relative movement.

15. The deposition device of claim 14, further comprising an actuator coupled to a susceptor receiving the substrate, the actuator configured to cause the first relative movement or the second relative movement between the injector module assembly and the substrate.

16. The deposition device of claim 15, further comprising a control unit configured to control a gas assembly to provide the source precursor or the reactant precursor to the first auxiliary gas injector and the second auxiliary gas injector according to an operation of the actuator.

17. The deposition device of claim 14, further comprising a body formed with:
a first exhaust configured to discharge excess source precursor remaining after injecting the source precursor onto the substrate by the first source injector, the first source injector placed within the first exhaust;
a second exhaust configured to discharge excess source precursor remaining after injecting the source precursor onto the substrate by the second source injector, the second source injector placed within the second exhaust; and
a third exhaust configured to discharge the reactant precursor remaining after injecting the reactant precursor onto the substrate by the reactant injector, the reactant injector placed within the third exhaust.

18. The deposition device of claim 17, further comprising:
a pressure controller configured to control pressure of the first exhaust, pressure of the second exhaust, and pressure of the third exhaust,
wherein during the first relative movement, the pressure controller is configured to lower the pressure of the first exhaust compared to the pressure of the third exhaust to route a portion of the reactant precursor to the first exhaust through a first passage below the first auxiliary gas injector, and
wherein during the second relative movement, the pressure controller is configured to lower the pressure of the second exhaust compared to the pressure of the third exhaust to route another portion of the reactant precursor to the second exhaust through a second passage below the second auxiliary gas injector.

19. The deposition device of claim 14, wherein the injector module assembly includes N number of reactor injectors, (N+1) number of source injectors, and 2N number of auxiliary gas injectors where N is an integer larger than 1, the reactor injectors and the source injectors interposed with each other, each auxiliary gas injector formed between one of the source injectors and one of the reactant injectors.
